(19) United States
(12) Patent Application Publication
(10) Pub. No.: US 2017/0250103 A1
(43) Pub. Date: Aug. 31, 2017

(54) FLUORO POLYMER CONTACT LAYER TO CARBON NANOTUBE CHUCK

(71) Applicant: Applied Materials, Inc., Santa Clara, CA (US)

(72) Inventors: Robert Jan VISSER, Menlo Park, CA (US); Sangmin JEONG, Palo Alto, CA (US); Ananth DODABALAPUR, Austin, TX (US)

(21) Appl. No.: 15/513,036

(22) PCT Filed: Sep. 17, 2015
(86) PCT No.: PCT/US2015/050591

§ 371 Date: Mar. 21, 2017

Related U.S. Application Data
(60) Provisional application No. 62/060,544, filed on Oct. 6, 2014.

(51) Int. Cl. H01L 21/687; C23C 16/458; C23C 16/26; C23C 16/50

(52) U.S. Cl. CPC H01L 21/68757; C23C 16/50; C23C 16/458; C23C 16/26

(57) ABSTRACT

Embodiments described herein generally relate to methods and apparatuses for manufacturing devices. An improved substrate support assembly having a fluoro polymer layer disposed at one or more interfaces between a substrate and a susceptor and method for processing a substrate utilizing the same are provided. The fluoro polymer layer disposed at one or more interfaces between the substrate and the susceptor allows the substrate to adhere firmly to the susceptor, and allows the substrate and the susceptor to withstand greater shear forces, thus minimizing movement between the substrate and the susceptor.

### BACKGROUND

Field

Embodiments described herein generally relate to methods and apparatuses for manufacturing devices using an improved substrate support assembly.

Description of the Related Art

Substrates, such as semiconductor substrates, solar panel substrates, or large area substrates or substrates in general, are often processed within chambers or other processing apparatuses. In order to evenly coat or process a substrate within the chamber, the substrate should be firmly attached to a susceptor within the chamber during processing to mitigate movement of the substrate. One way to attach the substrate to the susceptor is to use an electrostatic chuck as the substrate support assembly. The electrostatic chuck adheres the substrate to the susceptor through the application of electric fields and electrostatic forces. To remove the substrate, the electric fields and electrostatic forces are removed. However, there are several problems with electrostatic chucks. For example, electrostatic chucks can cause defects on the substrate, and the electrostatic chucks may degrade over time, thus contaminating substrates and requiring expensive maintenance or replacement. If the electrostatic chuck degrades over time, the substrate will no longer be firmly adhered to the susceptor, causing the substrate to move. If the substrate moves while on the susceptor, the substrate may not be evenly coated or processed.

Therefore, there is a need for an improved substrate support assembly that does not degrade over time and does not cause defects to the substrate.

### SUMMARY

Embodiments described herein generally relate to methods and apparatuses for manufacturing devices. An improved substrate support assembly having a fluoro polymer layer disposed at one or more interfaces between a substrate and a susceptor permits the substrate to adhere to the susceptor without the use of electric fields or electrostatic forces.

In one embodiment, a susceptor comprises a susceptor body having a first surface for supporting a substrate and a second surface opposite the first surface. A first fluoro polymer layer is disposed on the first surface of the susceptor body and a graphene layer disposed on the first fluoro polymer layer. The second surface of the susceptor body comprises anodized aluminum.

In another embodiment, a substrate comprises a polyimide layer disposed on a first surface of the substrate and a first fluoro polymer layer disposed on the polyimide layer. One or more thin film layers are disposed on a second surface of the substrate, the second surface of the substrate being opposite the first surface of the substrate.

In another embodiment, a method of processing a substrate comprises applying a polyimide layer to the substrate, applying a first fluoro polymer layer to the polyimide layer and inserting the substrate into a chamber. The substrate is then placed onto a susceptor having a graphene surface, wherein the fluoro polymer layer of the substrate contacts the graphene surface of the susceptor.

### BRIEF DESCRIPTION OF THE DRAWINGS

So that the manner in which the above recited features of the disclosure can be understood in detail, a more particular description of the disclosure, briefly summarized above, can be had by reference to embodiments, some of which are illustrated in the appended drawings. It is to be noted, however, that the appended drawings illustrate only examples of the embodiments and are therefore not to be considered limiting of its scope, for the disclosure can admit to other equally effective embodiments.

FIG. 1 is a cross section view of an illustrative vacuum processing chamber having a substrate support assembly.

FIGS. 2A-2B illustrate a susceptor, according to one embodiment.

FIGS. 3A-3B illustrate a substrate, according to one embodiment.

FIG. 4 is a schematic view of a substrate support assembly structure.

FIG. 5 is a flow diagram of a method for processing a substrate.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this disclosure and are therefore not to be considered limiting of its scope, for the disclosure may admit to other equally effective embodiments.

### DETAILED DESCRIPTION

Embodiments described herein generally relate to methods and apparatuses for manufacturing devices. An improved substrate support assembly having a fluoro polymer layer disposed at one or more interfaces between a substrate and a susceptor and method for processing a substrate utilizing the same are provided. The fluoro polymer layer disposed at one or more interfaces between the substrate and the susceptor allows the substrate to adhere firmly to the susceptor, and allows the substrate and the susceptor to withstand greater shear forces, thus minimizing movement between the substrate and the susceptor.

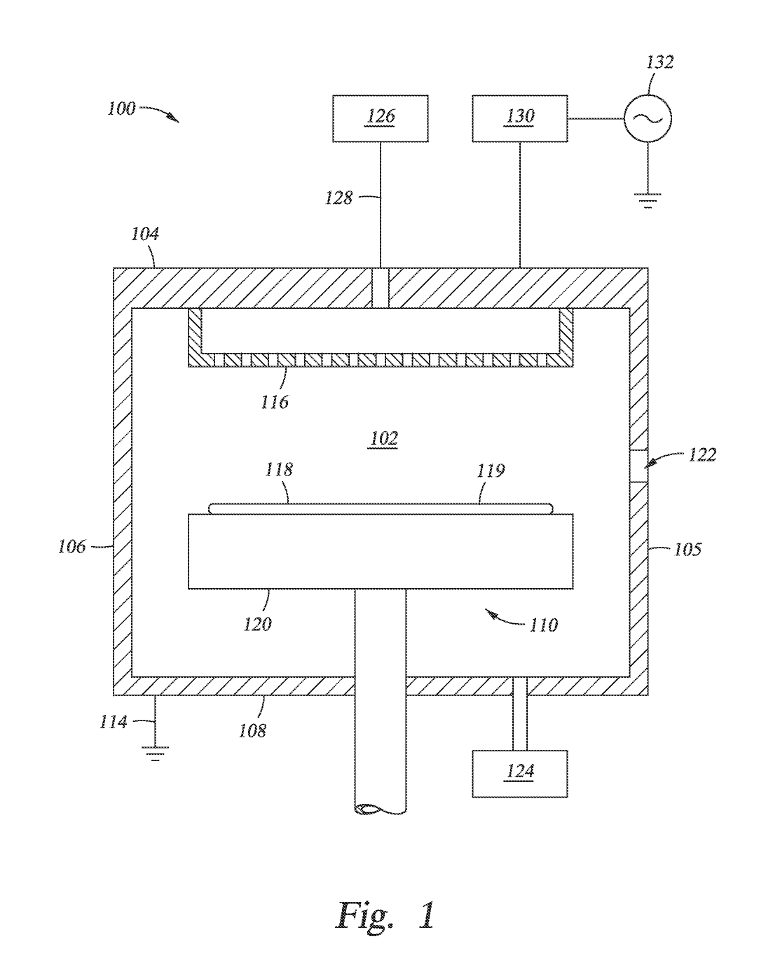

FIG. 1 shows a schematic side view of one embodiment of a vacuum processing chamber 100 having a substrate support assembly, such as a susceptor 110, on which a substrate 118 is processed. The vacuum processing chamber 100 may be used with a chemical vapor deposition (CVD) process, a physical vapor deposition (PVD) process, a plasma enhanced chemical vapor deposition (PECVD) process, an atomic layer deposition (ALD) process, an etching process or other common processes used for processing substrates.

The vacuum processing chamber 100 includes a chamber body 105 having a top 104, chamber sidewalls 106 and a chamber bottom 108 which are coupled to a ground 114. The top 104, the chamber sidewalls 106 and the chamber bottom 108 define an interior processing region 102. The chamber sidewalls 106 may include a substrate transfer port 122 to facilitate transferring the substrate 118 into and out of the vacuum processing chamber 100. The substrate transfer port 122 may be coupled to a transfer chamber and/or other chambers of a substrate processing system. The susceptor 110 has a susceptor body 120, and is disposed above the bottom 108 of the vacuum processing chamber 100 and holds the substrate 118 during deposition.

The dimensions of the chamber body 105 and related components of the vacuum processing chamber 100 are not limited and generally are proportionally larger than the size of the substrate 118 to be processed therein. Examples of substrate sizes include 200 mm diameter, 250 mm diameter, 300 mm diameter and 450 mm diameter, among others. The chamber body 105 is not limited to processing round substrates. Rather, the chamber body 105 may be shaped to handle polygonal substrates such as substrates having a surface area of between about 1600 cm² and about 90,000 cm² or more.

In one embodiment, a pumping device 124 is coupled to the bottom 108 of the vacuum processing chamber 100 to evacuate and control the pressure with the vacuum processing chamber 100. The pumping device 124 may be a conventional roughing pump, roots blower, turbo pump or other similar device that is adapted control the pressure in the interior processing region 102. In one example, the pressure level of the interior processing region 102 of the vacuum processing chamber 100 may be maintained at less than about 760 Torr.

A gas panel 126 supplies process and other gases through a gas line 128 into the interior processing region 102 of the chamber body 105. The gas panel 126 may be configured to provide one or more process gas sources, inert gases, non-reactive gases, and reactive gases, if desired. Examples of process gases that may be provided by the gas panel 126 include, but are not limited to, a silicon (Si) containing gases, carbon precursors and nitrogen containing gases. Examples of Si containing gases include Si-rich or Si-deficient nitride (SiₓN_{y}) and silicon oxide (SiO₂). Examples of carbon precursors include propylene, acetylene, ethylene, methane, hexane, hexane, isoprene, and butadiene, among others. Examples of Si containing gases include silane (SiH4), tetraethyl orthosilicate (TEOS). Examples of nitrogen and/or oxygen containing gases include pyridine, aliphatic amine, amines, nitriles, nitrous oxide, oxygen, TEOS, and ammonia, among others.

A showerhead 116 is disposed below the top 104 of the vacuum processing chamber 100 and is spaced above the susceptor 110. As such, the showerhead 116 is directly above a top surface 119 of the substrate 118 when positioned on the susceptor 110 for processing. One or more process gases provided from the gas panel 126 may supply reactive species through the showerhead 116 into the interior processing region 102.

The showerhead 116 may also function as an electrode for coupling power to gases within the interior processing region 102. It is contemplated that power may be coupled to the gases within the interior processing region 102 utilizing other electrodes or devices.

It is to be understood that while a showerhead has been shown in FIG. 1, processing and/or cleaning gas may be delivered to the chamber in other manners as well such as through sidewalls of the chamber. Additionally, rather than a showerhead, other objects are contemplated such as targets, heating lamps, cooling plates, etc that are found in substrate processing chambers. As such, the chamber disclosed herein should not be limited to a chamber having a showerhead.

In the embodiment depicted in FIG. 1, a power supply 132 may be coupled through a match circuit 130 to the showerhead 116. The RF energy applied to the showerhead 116 from the power supply 132 is inductively coupled to the process gases disposed in the interior processing region 102 to maintain a plasma in the vacuum processing chamber 100. Alternatively, or in addition to the power supply 132, power may be capacitively coupled to the process gases in the processing region 102 to maintain the plasma within the processing region 102. The operation of the power supply 132 may be controlled by a controller, (not shown), that also controls the operation of other components in the vacuum processing chamber 100.

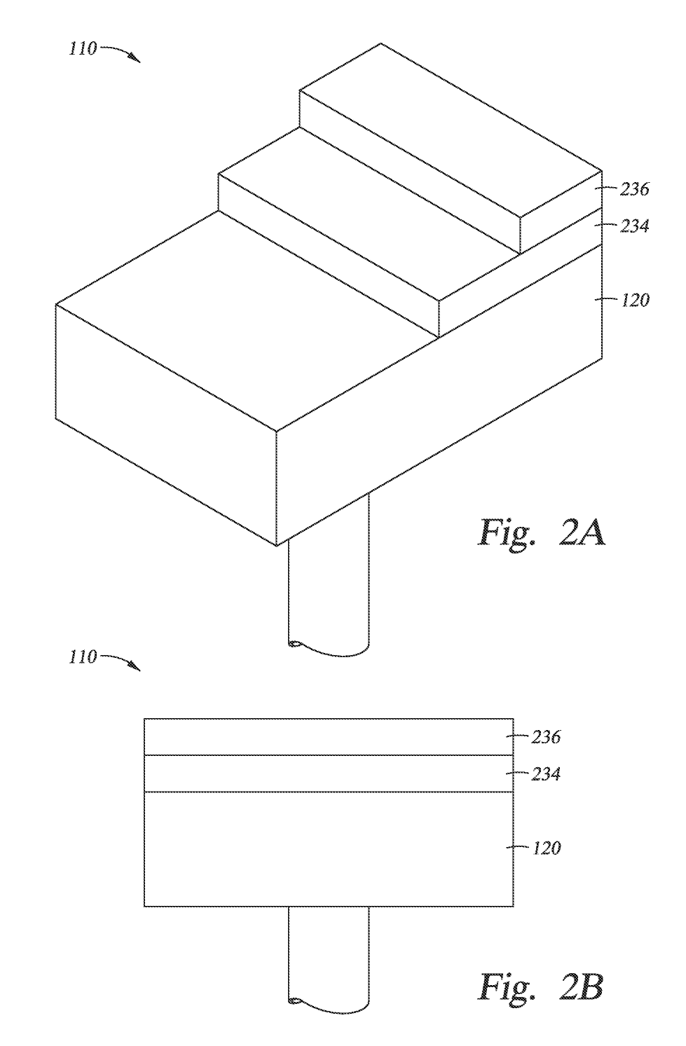

FIG. 2A illustrates a top perspective sectional view of the susceptor 110. FIG. 2B shows a side view of the susceptor 110. The susceptor 110 comprises a susceptor body 120. A fluoro polymer layer 234 is disposed on the susceptor body 120. The surface of the susceptor body 120 in contact with the fluoro polymer layer 234 may comprise anodized aluminum. A graphene layer 236 is disposed on the fluoro polymer layer 234. The fluoro polymer layer 234 and the graphene layer 236 in FIG. 2A are cut away to show the layering. The fluoro polymer layer 234 and the graphene layer 236 in FIG. 2A are applied to the entire surface of the susceptor body 120, as shown in FIG. 2B.

Suitable materials for the fluoro polymer layer include ethylene tetrafluoroethylene (ETFE), ethylene chlorotrifluoroethylene (ECTFE), polytetrafluoroethylene (PTFE), polyvinylfluoride (PVF), polyvinylidene fluoride (PVDF), polychlorotrifluoroethylene (PCTFE), fluorinated ethylene propylene (FEP), and perfluoroalkoxy (PFA).

In one embodiment, the susceptor body 120 comprises aluminum. The aluminum may be anodized aluminum. In another embodiment, the susceptor body 120 comprises carbon nanotube. The susceptor body 120 may also include a heading element formed therein. The fluoro polymer layer 234 may have a thickness within a range of about 10 angstroms to about 20 angstroms, and the graphene layer 236 may have a thickness within a range of about 10 angstroms to about 20 angstroms.

Applying the fluoro polymer layer 234 between the graphene layer 236 and the susceptor body 120 allows the graphene layer 236 to be securely attached to the susceptor body 120 without the use of electric fields, electrostatic force, or by other common means used to adhere the graphene layer 236 to the susceptor body 120. By utilizing the surface forces between the graphene layer 236 and the fluoro polymer layer 234, and between the susceptor body 120 and the fluoro polymer layer 234, the graphene layer 236 is sturdily adhered to the susceptor body 120, and the graphene layer 236 and the susceptor body 120 are able to withstand a greater shear force. The fluoro polymer layer 234 acts as a contact layer between the graphene layer 236 and the susceptor body 120, strengthening the surface forces between the graphene layer 236 and the susceptor body 120 and effectively reducing movement between the graphene layer 236 and the susceptor body 120.

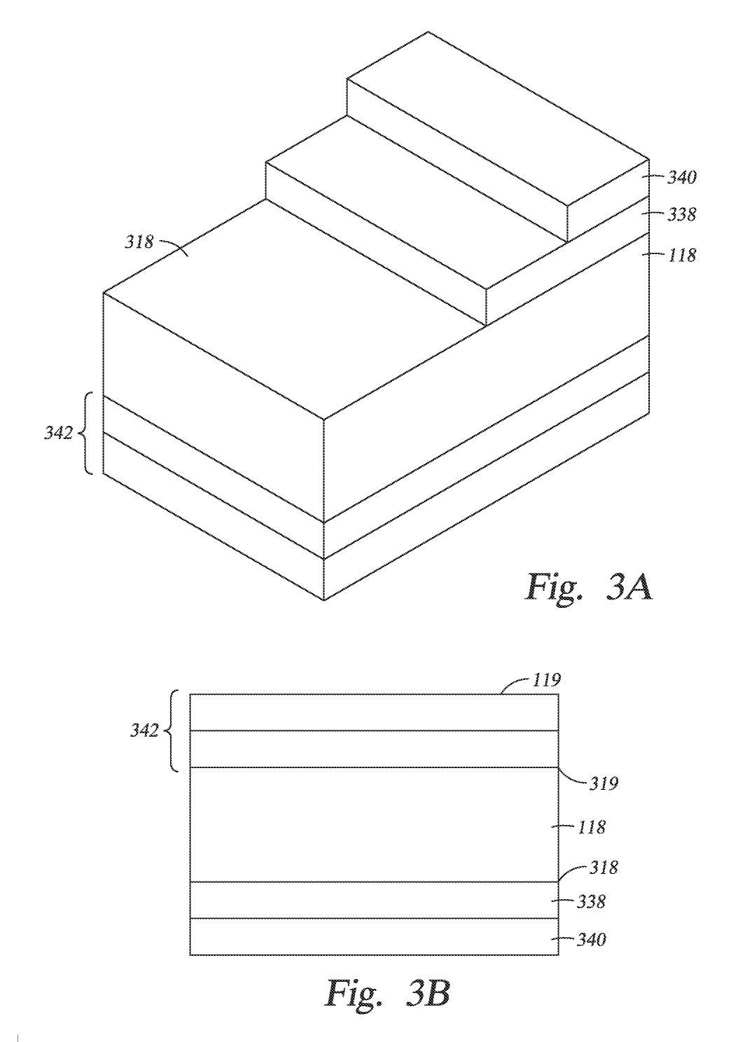

FIG. 3A illustrates a bottom perspective sectional view of the substrate 118 having additional layers. FIG. 3B shows a side view of the substrate 118 having additional layers. A polyimide layer 338 is disposed on a first surface 318 of the substrate 118. A fluoro polymer layer 340 is disposed on polyimide layer 338. On a second surface 319 of the substrate 118 are one or more thin film layers 342. The thin film layers 342 may be the top surface 119 of the substrate 118 of FIG. 1. In one embodiment, the thin film layers 342 may not be present, and the second surface 319 of the substrate may be the top surface 119. Though only two thin film layers 342 are depicted in FIGS. 3A-3B, any number of thin film layers 342 may be deposited on the second surface 319 of the substrate 118. The fluoro polymer layer 340 and the polyimide layer 338 in FIG. 3A are cut away to show the layering. The fluoro polymer layer 340 and the polyimide layer 338 in FIG. 3A are applied to the entire surface of the substrate 118, as shown in FIG. 3B.

In one embodiment, the substrate 118 comprises a semiconductor material. In another embodiment, the substrate 118 comprises sapphire. In yet another embodiment, the substrate 118 comprises glass. The fluoro polymer layer 340 may have a thickness within a range of about 10 angstroms to about 20 angstroms. The polyimide layer 338 may have a thickness within a range of about 10 angstroms to about 20 angstroms.

Applying the fluoro polymer layer 340 to the polyimide layer 338 places the substrate 118 in condition to be positioned on a susceptor, such as susceptor 110. The side of the substrate 118 on which the fluoro polymer layer 340 is disposed will be placed onto a surface of the susceptor, such as a graphene surface. The fluoro polymer layer 340 acts as a contact layer, and utilizes surface forces between the fluoro polymer layer 340 and the polyimide layer 338, and between the fluoro polymer layer 340 and the surface of the susceptor, such as graphene layer 236 of FIGS. 2A-2B. The fluoro polymer contact layer 340 allows the substrate 118 to be firmly attached to a susceptor through surface forces.

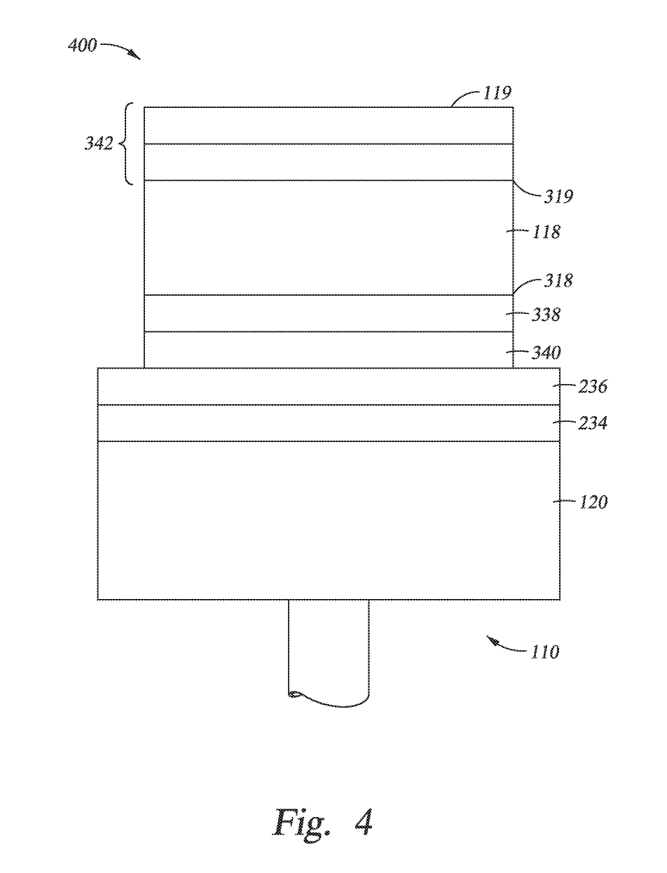

FIG. 4 illustrates a substrate support assembly structure 400. As shown in FIG. 4, disposed on the susceptor body 120 is a first fluoro polymer layer 234. A graphene layer 236 is disposed on the first fluoro polymer layer 234. A second fluoro polymer layer 340 is disposed on the graphene layer 236. Disposed on the second fluoro polymer layer 340 is a polyimide layer 338. The polyimide layer 338 is disposed on a first surface 318 of the substrate 118. On a second surface 319 of the substrate 118 are one or more thin film layers 342. The thin film layers 342 are the top surface 119 of the substrate 118 facing a showerhead, such as showerhead 116 of FIG. 1.

The second fluoro polymer layer 340 acts as a contact layer between the polyimide layer 338 and the graphene layer 236, and advantageously utilizes surface forces between the second fluoro polymer layer 340 and the polyimide layer 338, and between the second fluoro polymer layer 340 and the graphene layer 236 to diminish movement between the susceptor 110 and the substrate 118. Specifically, placing the second fluoro polymer contact layer 340 between the polyimide layer 338 and the graphene layer 236 results in strong dipolar surface forces at both interfaces, minimizing movement between the layers 236, 338. Both the fluoro polymer layer 340 and the polyimide layer 338 are polar, which results in the dipolar surface forces between the layers 338, 340. The graphene layer 236 is able to be polarized, also resulting in strong dipolar forces with the fluoro polymer layer 340. The dipolar surface forces are attractive forces between the second fluoro polymer layer 340 and both the polyimide layer 338 and the graphene layer 236, which effectively adheres the polyimide layer 338 to the graphene layer 236 through the fluoro polymer contact layer 340.

The dipolar surface forces at the interfaces act in a Velcro®-like fashion at a molecular level. Adding the second fluoro polymer layer 340 between the graphene layer 236 and the polyimide layer 338 allows the layers 236, 338 to withstand a greater shear force. The ability of the layers 236, 338 to withstand shear forces is much greater than the ability of the layers 236, 338 to withstand vertical forces. Thus, the layers may be removed vertically, but have a difficult time moving horizontally in either direction, much like Velcro®. This allows for the several substrates to be accurately processed on the susceptor 110 over time, as the substrates are able to be placed and removed vertically, but have very minimal movement horizontally while being processed.

The same phenomenon occurs at the interface between the first fluoro polymer layer 234 and the susceptor body 120. The first fluoro polymer layer 234 is polar and acts as a contact layer between the graphene layer 236 and the susceptor body 120, as discussed above. The strong dipolar surface forces between the first fluoro polymer contact layer 234 and both the graphene layer 236 and the susceptor body 120 also act in a Velcro®-like fashion, allowing the layers to withstand a greater shear force. This allows the graphene layer 236 to be securely attached to the susceptor 110, diminishing movement between all the layers of the structure 400.

Since the fluoro polymer contact layers 234, 340 utilize surface forces, the fluoro polymer layers 234, 340 do not degrade over time, nor do the fluoro polymer layers 234, 340 cause defects to the substrate 118. As the fluoro polymer layer 340 is disposed on the side 318 of the substrate 118 opposite the top surface 119, the top surface 119 is able to be processed while the substrate 118 remains securely adhered to the susceptor 110. Thus, defects to the substrate 118 are minimized and the substrate 118 is able to be evenly coated and/or processed.

There are several ways the structure 400 of FIG. 4 may be configured. In one embodiment, the structure 400 may be comprised by placing the substrate 118 of FIGS. 3A-3B onto the susceptor 110 of FIGS. 2A-2B. In this embodiment, the susceptor 110 comprises a first fluoro polymer layer 234 disposed on the susceptor body 120 and a graphene layer 236 on the first fluoro polymer layer 234. The substrate 118 comprises one or more thin film layers 342 disposed on a second surface 319, a polyimide layer 338 disposed on a first surface 318, and a second fluoro polymer layer 340 disposed on the polyimide layer 338. The second fluoro polymer layer 340 of the substrate 118 is then placed onto the graphene layer 236 of the susceptor 110. The top surface 119 of the substrate 118 is then ready to be processed.

In another embodiment, the susceptor 110 comprises only the susceptor body 120. The substrate 118 then comprises a first fluoro polymer layer 234 disposed on a graphene layer 236, the graphene layer 236 disposed on a second fluoro polymer layer 340, the second fluoro polymer layer 340 disposed on a polyimide layer 338, the polyimide layer 338 being disposed on a first surface 318 of the substrate 118. On a second surface 319 of the substrate 118 are one or more thin film layers 342. The first fluoro polymer layer 234 is then placed onto the susceptor body 120. In this embodiment, the first fluoro polymer layer 234 has a thickness within a range of about 10 angstroms to about 20 angstroms, while the second fluoro polymer layer 340 has a thickness within a range of about 10 angstroms to about 20 angstroms.

In yet another embodiment, the susceptor 110 comprises a first fluoro polymer layer 234 disposed on the susceptor body 120, a graphene layer 236 disposed on the first fluoro polymer layer 234, a second fluoro polymer layer 340 disposed on the graphene layer 236, and a polyimide layer 338 disposed on the second fluoro polymer layer 340. The substrate 118 then comprises only the one or more thin film layers 342 disposed on the second surface 319. The first surface 318 of the substrate 118 is placed on the polyimide layer 338 of the susceptor 110.

In another embodiment, the graphene layer 236 is disposed directly onto the susceptor body 120, eliminating the first fluoro polymer layer 234. In this embodiment, the second fluoro polymer layer 340 is still disposed between the polyimide layer 338 and the graphene layer 236, effectively minimizing movement between the susceptor 110 and the substrate 118. The substrate 118 then comprises the polyimide layer 338 disposed on a first surface 318 and the second fluoro polymer layer 340 disposed on the polyimide layer 338. On a second surface 319 of the substrate 118 are one or more thin film layers 342. The graphene layer 236 may be disposed directly onto the susceptor body 120, or the graphene layer 236 may be disposed onto the second fluoro polymer layer 340, which would then be placed onto the susceptor body 120, readying the substrate 118 for processing.

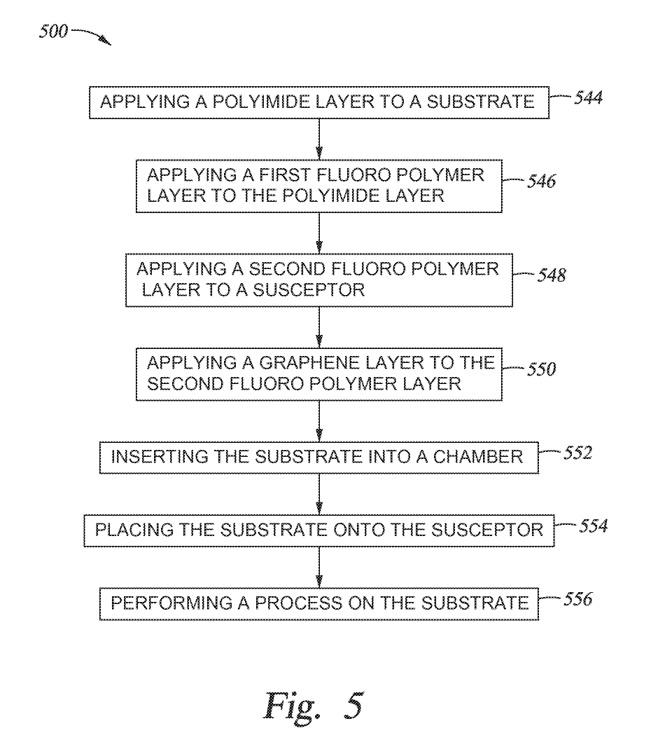

FIG. 5 is a flow diagram of a method 500 of processing a substrate, such as substrate 118. In box 544, a polyimide layer is applied to a first surface of the substrate. The polyimide layer may be polyimide layer 338 from FIGS. 3A-3B. In one embodiment, the polyimide layer is applied using a CVD process. It is to be understood that the polyimide layer could be applied using other deposition techniques common in the art, such as PVD, PECVD, or ALD.

In box 546, a first fluoro polymer layer is applied to the polyimide layer. The first fluoro polymer layer may be the fluoro polymer layer 340 from FIGS. 3A-3B. In box 548, a second fluoro polymer layer is applied to a first surface of a susceptor. The second fluoro polymer layer and the susceptor may be the fluoro polymer layer 234 the susceptor 110 of FIGS. 2A-2B. The first surface of the susceptor may be anodized aluminum. In box 550, a graphene layer is applied to the second fluoro polymer layer. The graphene layer may be the graphene layer 236 of FIGS. 2A-2B.

The first fluoro polymer layer, the second fluoro polymer layer, and the graphene layer may be applied using the same CVD process used to apply the polyimide layer, or the first fluoro polymer layer, the second fluoro polymer layer, and the graphene layer may be applied using another process, such as PVD, PECVD, or ALD. The first fluoro polymer layer, the second fluoro polymer layer, and the graphene layer may all be applied used the same technique, or the first fluoro polymer layer, the second fluoro polymer layer, and the graphene layer may be applied using different techniques.

In box 552, the substrate is inserted into a chamber. The substrate may be inserted through the substrate transfer port 122 of vacuum process chamber 100, as shown in FIG. 1. The chamber may be any type of process chamber previously discussed above.

In box 554, the substrate is placed onto the susceptor. Specifically, the first fluoro polymer layer of the substrate is placed onto the graphene layer of the susceptor, with the first fluoro polymer layer acting as a contact layer between the graphene layer and the polyimide layer. The first fluoro polymer layer is placed onto the graphene layer to facilitate a strong resistance to shear forces between the substrate and the susceptor, and to minimize movement between the substrate and the susceptor.

In box 556, a process is performed on the substrate. The process may be performed by utilizing the showerhead 116 of FIG. 1. In one embodiment, the process performed on the substrate is PECVD. The process may be any process common in the art, such as CVD, PVD, ALD, etching, or annealing.

Thus, the methods and apparatuses described herein advantageously mitigate movement between a substrate and a susceptor. The improved substrate support assembly having a fluoro polymer layer disposed at one or more interfaces between a substrate and a susceptor and method for processing a substrate utilizing the same allows a substrate to be accurately coated or processed without degrading overtime and with minimal defects. The fluoro polymer layer disposed at one or more interfaces between the substrate and the susceptor firmly adheres the substrate to the susceptor without the use of electrostatic forces, eliminating any defects caused by electrostatic forces or electric fields. The fluoro polymer layer disposed at one or more interfaces between the substrate and the susceptor allows the substrate and the susceptor to withstand greater shear forces, thus reducing movement between the substrate and the susceptor.

While the foregoing is directed to embodiments of the present disclosure, other and further embodiments can be devised without departing from the basic scope thereof, and the scope thereof is determined by the claims that follow.

We claim:

1. A susceptor, comprising:
a susceptor body having a first surface for supporting a substrate and a second surface opposite the first surface;
a first fluoro polymer layer disposed on the first surface of the susceptor body; and
a graphene layer disposed on the first fluoro polymer layer, wherein the second surface of the susceptor body comprises anodized aluminum.

2. The susceptor of claim 1, wherein a second fluoro polymer layer is disposed on the graphene layer.

3. The susceptor of claim 2, wherein a polyimide layer is disposed on the second fluoro polymer layer.

4. The susceptor of claim 1, wherein the susceptor body comprises aluminum.

5. The susceptor of claim 4, wherein the susceptor body comprises anodized aluminum.

6. The susceptor of claim 1, wherein the susceptor body includes a heating element formed therein.

7. The susceptor of claim 1, wherein the first fluoro polymer layer has a thickness within a range of about 10 angstroms to about 20 angstroms and the graphene layer has a thickness within a range of about 10 angstroms to about 20 angstroms.

8. A substrate, comprising:
a polyimide layer disposed on a first surface of the substrate;
a first fluoro polymer layer disposed on the polyimide layer; and
one or more thin film layers disposed on a second surface of the substrate, the second surface of the substrate being opposite the first surface of the substrate.

9. The substrate of claim 8, wherein a graphene layer is disposed on the first fluoro polymer layer.

10. The substrate of claim 9, wherein a second fluoro polymer layer is disposed on the graphene layer.

11. The substrate of claim 10, wherein the second fluoro polymer layer has a thickness within a range of about 10 angstroms to about 20 angstroms.

12. The substrate of claim 8, wherein the first fluoro polymer layer has a thickness within a range of about 10 angstroms to about 20 angstroms and the polyimide layer has a thickness within a range of about 10 angstroms to about 20 angstroms.

13. The substrate of claim 8, wherein the substrate comprises a semiconductor material, a sapphire, or glass.

14. A method of processing a substrate, comprising:
applying a polyimide layer to the substrate;
applying a first fluoro polymer layer to the polyimide layer;
inserting the substrate into a chamber; and
placing the substrate onto a susceptor having a graphene surface, wherein the fluoro polymer layer of the substrate contacts the graphene surface of the susceptor.

15. The method of claim 18, wherein the first fluoro polymer layer has a thickness within a range of about 10 angstroms to about 20 angstroms and the polyimide layer has a thickness within a range of about 10 angstroms to about 20 angstroms.
